(19) United States
(12) Patent Application Publication
(10) Pub. No.: US 2016/0343863 A1
(43) Pub. Date: Nov. 24, 2016

(54) OXIDE THIN FILM TRANSISTOR AND MANUFACTURING METHOD THEREOF

(71) Applicant: SHENZHEN CHINA STAR OPTOELECTRONICS TECHNOLOGY CO. LTD., Shenzhen, Guangdong (CN)

(72) Inventor: Shipeng CHI, Shenzhen, Guangdong (CN)

(73) Assignee: Shenzhen China Star Optoelectronics Technology Co. Ltd., Shenzhen, Guangdong (CN)

(21) Appl. No.: 14/433,858

(22) PCT Filed: Feb. 28, 2015
(86) PCT No.: PCT/CN2015/073406

§ 371 Date: Apr. 6, 2015

(30) Foreign Application Priority Data
Jan. 27, 2015 (CN) 201510042064.2

(51) Int. Cl. H01L 29/786; H01L 23/31; H01L 29/51; H01L 29/40; H01L 29/49; H01L 29/66

(52) U.S. Cl. CPC H01L 29/7869; H01L 29/4908; H01L 29/66969; H01L 29/518; H01L 29/401; H01L 23/3171; H01L 29/4966

(57) ABSTRACT

The invention provides an oxide thin film transistor and a manufacturing method thereof. The manufacturing method includes sequentially forming a gate electrode, a gate insulating layer and an oxide semiconductor film on a first substrate; sequentially forming a first metal layer and a second metal layer on the oxide semiconductor film, and forming a drain electrode and a source electrode on the second metal layer, the drain electrode and the source electrode being separated by a channel and the channel exposing a portion of the first metal layer; oxidizing the exposed portion of the first metal layer; forming an insulating passivation layer and disposing contact electrodes. By the above solution, the invention can protect a back channel of the oxide thin film transistor and meanwhile can simplify manufacturing process and reduce cost.

### TECHNICAL FIELD

The invention relates to the display field, and particularly to an oxide thin film transistor and a manufacturing method thereof.

### DESCRIPTION OF RELATED ART

Along with the development of flat panel display devices using LCD displays and OLED displays as representatives toward the directions of large size and high resolution, thin film transistors (TFTs) as a core component of the flat panel display industry have attracted wide publicity.

Commonly used thin film transistors in the prior art include amorphous silicon thin film transistors and oxide thin film transistors; the oxide thin film transistors have advantages of high carrier mobility and without significantly changing existing LCD panel production lines when being introduced, and therefore have been widely used.

The oxide thin film transistors include two types of structures of top-gate and bottom-gate. The bottom-gate structure mainly uses an etch stop (ES) type structure or a back channel etch (BCE) type structure. In the etch stop type structure, an etch stop layer is disposed on a back channel and used as an etching protective layer when etching source/drain electrodes so as to avoid damage to the back channel. However, compared with the BCE type structure, one mask is needed to be added when forming the etching protective layer and thus six masks in total are needed to finish the manufacturing of thin film transistor. Therefore, the ES type structure increases the process complexity and manufacturing cost, and the etching protective layer causes the increase of parasitic capacitance to the thin film transistor so that the device size is not easy to be reduced. The BCE type structure although only needs five mask during the manufacturing thereof, and compared with the ES type structure, can simplify the manufacturing process and reduce manufacturing cost, but it is easy to cause damage to the back channel when etching source/drain electrodes or depositing an passivation layer. For example, if a dry etching method is used, when forming the source/drain electrodes by the dry etching, plasma formed by an etching gas would bombard the back channel, the plasma bombardment would cause the back channel to produce more defects, which would influence the normal use of the thin film transistor; if a wet etching method is used, when forming the source/drain electrodes by the wet etching, an etchant would corrode an active layer oxide, the back channel is damaged and the characteristics of the oxide thin film transistor would be affected.

### SUMMARY

A technical problem mainly to be solved by the invention is to provide an oxide thin film transistor and a manufacturing method thereof, which can protect a back channel of oxide thin film transistor and meanwhile can simplify manufacturing process and reduce cost.

In order to solve the above technical problem, a technical solution proposed by the invention is to provide a manufacturing method of an oxide thin film transistor. The manufacturing method includes: depositing a metal film on a first substrate and forming a gate electrode by exposure and etching on the metal film; sequentially depositing a gate insulating layer and an oxide semiconductor film; sequentially forming a first metal layer and a second metal layer on the oxide semiconductor film, and etching the second metal layer by a half-tone mask process, a gray-tone mask process or a single slit mask process to form a channel and a pattern of active regions of a drain electrode and a source electrode separated by the channel; etching off a part of the second metal layer outside the pattern of the active regions; etching off a part of the second metal layer corresponding to the channel to expose a portion of the first metal layer; oxidizing the exposed portion of the first metal layer; forming an insulating layer and disposing contact electrodes.

In an embodiment, the step of oxidizing the exposed portion of the first metal layer includes: using an oxygen plasma to oxidize the exposed portion of the first metal layer to thereby form a metal oxide layer for protecting the channel.

In an embodiment, the gate insulating layer includes at least one of silicon nitride (SiNx) and amorphous silicon oxide (SiOx); the oxide semiconductor film is a transparent oxide and includes at least one of zinc oxide (ZnO) based, tin dioxide (SnO₂) based and indium oxide (In₂O₃) based transparent oxides.

In an embodiment, the first substrate includes one of glass substrate and quartz substrate; the metal film includes at least one of aluminium (Al), molybdenum (Mo), copper (Cu) and silver (Ag).

In an embodiment, a thickness of the first metal layer is 5 nm to 10 nm (i.e., in the range from 5 nm to 10 nm).

In an embodiment, the step of forming an insulating passivation layer and disposing contact electrodes includes: depositing the insulating passivation layer, forming contact holes on the insulating passivation layer by etching, and forming the contact electrodes in the contact holes.

In an embodiment, the insulating passivation layer includes at least one of silicon nitride (SiNx) and amorphous silicon oxide (SiOx); the contact electrodes are indium tin oxide (ITO) electrodes.

In order to solve the above technical problem, another technical solution proposed by the invention is to provide a manufacturing method of an oxide thin film transistor. The manufacturing method includes: sequentially forming a gate electrode, a gate insulating layer and an oxide semiconductor film in that order on a first substrate; sequentially forming a first metal layer and a second metal layer in that order on the oxide semiconductor film, and forming a drain electrode and a source electrode on the second metal layer, the source electrode and the drain electrode being separated by a channel, and the channel exposing a portion of the first metal layer; oxidizing the exposed portion of the first metal layer; forming an insulating passivation layer and disposing contact electrodes.

In an embodiment, the step of sequentially forming a first metal layer and a second metal layer in that order on the oxide semiconductor film, and forming a drain electrode and a source electrode on the second metal layer, the source and the drain being separated by a channel, and the channel exposing a portion of the first metal layer includes: etching the second metal layer by a half-tone mask process, a gray-tone mask process or a single slit mask process to form the channel and a pattern of active regions of the drain electrode and the source electrode separated by the channel; etching off a portion of the second metal layer outside the pattern of the active regions; etching off a portion of the second metal layer corresponding to the channel to expose the portion of the first metal layer.

In an embodiment, the step of oxidizing the exposed portion of the first metal layer includes: using an oxygen plasma to oxidize the portion of the first metal layer to thereby form a metal oxide layer for protecting the channel.

In an embodiment, the step of sequentially forming a gate electrode, a gate insulating layer and an oxide semiconductor film in that order on a first substrate includes: depositing a metal film on the first substrate and forming the gate electrode by exposure and etching on the metal film; sequentially depositing the gate insulating layer and the oxide semiconductor film.

In an embodiment, the gate insulating layer includes at least one of silicon nitride (SiNx) and amorphous silicon oxide (SiOx); the oxide semiconductor film is a transparent oxide and comprises at least one of zinc oxide (ZnO) based, tin dioxide (SnO₂) based and indium oxide (In₂O₃) base transparent oxides.

In an embodiment, the first substrate includes a glass substrate or a quartz substrate; the metal film includes at least one of aluminium (Al), molybdenum (Mo), copper (Cu) and silver (Ag).

In an embodiment, a thickness of the first metal layer is 5 nm to 10 nm.

In an embodiment, the step of forming an insulating passivation layer and depositing contact electrodes includes: depositing the insulating passivation layer, forming contact holes on the insulating passivation layer by etching, and forming the contact electrodes in the contact holes.

In an embodiment, the insulating passivation layer includes at least one of silicon nitride (SiNx) and amorphous silicon oxide (SiOx); the contact electrodes are indium tin oxide (ITO) electrodes.

In order to solve the above technical problem, still another technical solution proposed by the invention is to provide an oxide thin film transistor. The oxide thin film transistor includes: a first substrate, a gate electrode disposed on the first substrate, a gate insulating layer disposed on the gate electrode and an oxide semiconductor film disposed on the gate insulating layer. The oxide thin film transistor further includes a first metal layer disposed on the oxide semiconductor film, and a source electrode and a drain electrode separated by a channel and disposed on the first metal layer, the channel exposing a metal oxide layer formed by an oxidized portion of the first metal layer. The oxide thin film transistor still further includes an insulating passivation layer, the insulating passivation layer being disposed overlying the drain electrode, the metal oxide layer and the source electrode, the insulating passivation layer further being disposed with contact electrodes.

The efficacy can be achieved by the invention is that: different from the prior art, the manufacturing method of an oxide thin film transistor associated with the above embodiments includes after forming a gate electrode, a gate insulting layer and an oxide semiconductor film on a first substrate, sequentially forming a first metal layer and a second metal layer on the oxide semiconductor film, a special mask is used to etch the second metal layer so as to simultaneously form a channel and a pattern of active regions of a source electrode and a drain electrode separated by the channel, for this process, compared with the prior art, one mask process can be reduced, the manufacturing process of the oxide thin film transistor can be simplified, manufacturing time and cost can be reduced. Moreover, the exposed portion of the first metal layer at the location of the channel is oxidized to form an etching protective layer for protecting a back channel, and during the oxidization process of the first metal layer, there is no need of mask, compared with the prior art, it not only reduces one mask again, but also the etching protective layer can prevent the back channel from damage during etching the source electrode and drain electrode or depositing the insulating passivation layer, and thus can further effectively improve the characteristics of the oxide thin film transistor.

### BRIEF DESCRIPTION OF THE DRAWINGS

The above and other aspects, features and advantages of embodiments of the invention will be more apparent from the following detailed description taken in conjunction with the accompanying drawings, in which:

FIG. 1 is a flowchart of an embodiment of a manufacturing method of an oxide thin film transistor of the invention; and

FIG. 2 is a schematic cross-sectional structural view of an embodiment of an oxide thin film transistor of the invention.

### DETAILED DESCRIPTION OF EMBODIMENTS

In the following, various embodiments of the invention will be described in detail with reference to accompanying drawings. The invention may be embodied in many different forms and should not be construed as limiting to the embodiments set forth herein. Rather, these embodiments are provided to explain the principles of the invention and its practical applications, so that other skilled in the art can understand various embodiments of the invention and various modifications suitable for specific intended applications. In the drawings, same reference numerals will be used to represent the same components.

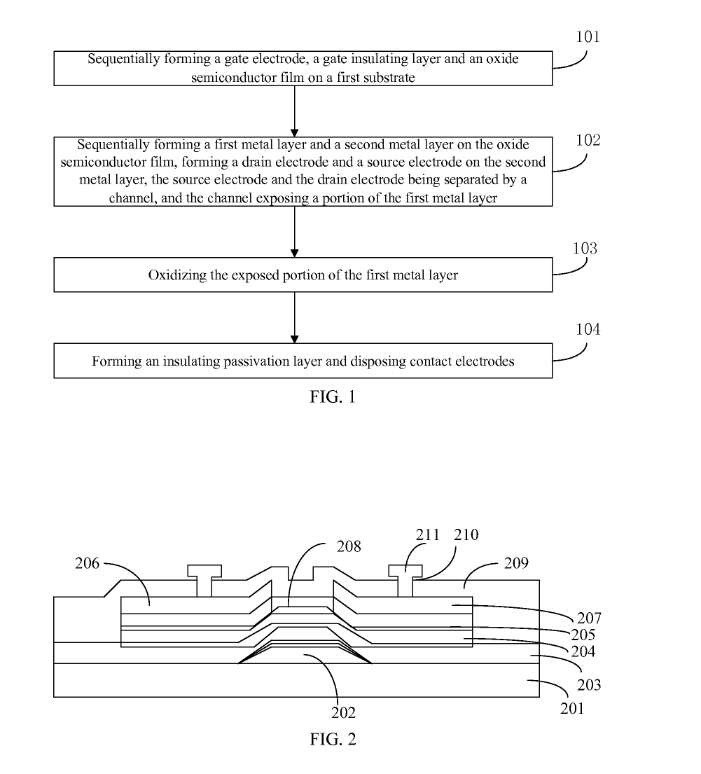

Referring to FIG. 1, a flowchart of an embodiment of a manufacturing method of an oxide thin film transistor of the invention is shown. The manufacturing method in this embodiment includes the following steps.

101: sequentially forming a gate electrode, a gate insulating layer and an oxide semiconductor film in that order on a first substrate.

Specifically, a metal film is firstly formed on the first substrate by a deposition process, a first mask is used to perform an exposure on the metal film, and then the metal film is etched to form the gate electrode. The first mask is an ordinary mask only for etching one layer.

The first substrate may be a glass substrate or a quartz substrate; in other embodiment, other substrate may be used and is not limited herein.

The metal film includes at least one of aluminium (Al), molybdenum (Mo), copper (Cu) and silver (Ag); and in other embodiment, other metal ma be used and is not limited herein.

A deposition process generally is that depositing a foreign substance(s) on a substrate surface to form a thin film, also is referred to as vapor deposition. In this embodiment, a metal substance(s) is/are deposited on a surface of the first substrate to form the metal film. In other embodiment, other deposition method may be used to form the metal film and it is not limited herein.

An etching process generally is a process of removing a part of a thin film unmasked by a resist film and thereby forming a pattern on the thin film same as that of the resist film. The etching process generally is drying etching or wet etching, and in this embodiment it is not limited as long as it can etch the metal film to form the gate electrode.

After the gate electrode is formed, the gate insulating layer and the oxide semiconductor film are sequentially deposited on a surface of the gate electrode.

The gate insulating layer includes at least one of silicon nitride (SiNx) and amorphous silicon oxide (SiOx); and in other embodiment, other insulating substance may be used and is not limited herein.

The oxide semiconductor film is a transparent oxide and includes at least one of zinc oxide (ZnO) based, tin dioxide (SnO₂) based and indium oxide (In₂O₃) based transparent oxides; and in other embodiment, other transparent oxide may be used as long as it can achieve the function of the oxide semiconductor film in this embodiment and is not limited herein.

102: sequentially forming a first metal layer and a second layer on the oxide semiconductor film and forming a drain electrode and a source electrode on the second metal layer, the source electrode and the drain electrode being separated by a channel, and the channel exposing a portion of the first metal layer.

In particular, after forming the gate electrode, the gate insulating layer and the oxide semiconductor film on the first substrate, the first metal layer and the second metal layer are sequentially deposited on the oxide semiconductor film.

The first metal layer is thin and generally includes at least one of metals such as aluminium (Al) and titanium (Ti); and in other embodiment, other metal with the same property may be used and is not limited herein. A thickness of the first metal layer is 5 nm-10 nm, i.e., in the range from 5 nm to 10 nm.

A second mask is used to perform an etching on the second metal layer, so as to form the channel and a pattern of active regions of the drain electrode and the source electrode separated by the channel. The drain electrode and the source electrode are separated by the channel and located at two sides of the gate electrode respectively.

The second metal layer includes at least molybdenum (Mo) and silver (Ag); and in other embodiment, other metal with the same property may be used and is not limited herein.

The second mask includes one of half-tone process, gray-tone mask process and single slit mask process; and in other embodiment, other process may be used as long as it can achieve the patterning of the active regions of the drain electrode and the source electrode by one time of mask and is not limited herein.

After the active regions of the drain electrode and the source electrode are patterned, a part of the second metal layer outside the pattern of the active regions of the drain electrode and the source electrode is etched off and a part of the second metal layer corresponding to the channel also is etched off to expose a portion of the first metal layer in the location of the channel.

In another embodiment, a photoresist is disposed overlying a surface of the second metal layer, and when etching the second metal layer to form the channel, the photoresist also is etched to expose the portion of the first metal layer in the location of the channel.

103: oxidizing the exposed portion of the first metal layer.

In this embodiment, an oxygen plasma is used to oxidize the exposed portion of the first metal layer. Preferably, the exposed first metal layer in the channel region all is oxidized to form an etching protective layer for protecting a back channel.

In another embodiment, an atmosphere containing oxygen plasma may be used to oxidize the exposed portion of the first metal layer instead and is not limited herein.

104: forming an insulating passivation layer and disposing contact electrodes.

After the gate electrode, the source electrode and the drain electrode of an oxide thin film transistor are formed, the insulating passivation layer is deposited on a surface of the oxide thin film transistor and a third mask is used to form contact holes on the insulating passivation layer by etching.

A fourth mask is used to form contact electrodes in the contact holes.

The third mask and the fourth mask each are an ordinary mask only for etching one layer.

The insulating passivation layer includes at least one of silicon nitride (SiNx) and amorphous silicon oxide (SiOx); and in other embodiment, other insulating passivation substance with the same property may be used and is not limited herein. The contact electrodes are indium tin oxide (ITO) electrodes, and in other embodiment, the ITO electrodes can be replaced by other electrode according to the need and are not limited herein.

Different from the prior art, the manufacturing method of an oxide thin film transistor in this embodiment includes after forming a gate electrode, a gate insulting layer and an oxide semiconductor film on a first substrate, sequentially forming a first metal layer and a second metal layer on the oxide semiconductor film, a special mask is used to etch the second metal layer so as to simultaneously form a channel and pattern active regions of a source electrode and a drain electrode separated by the channel, for this process, compared with the prior art, one mask process can be reduced, the manufacturing process of the oxide thin film transistor can be simplified, manufacturing time and cost can be reduced. Moreover, the exposed portion of the first metal layer in the location of the channel is oxidized to form an etching protective layer for protecting a back channel, and during the oxidization process of the first metal layer, there is no need of mask, compared with the prior art, it not only reduces one mask again, simplifies the manufacturing process of the oxide thin film transistor and reduces the manufacturing time and cost, but also can avoid the parasitic capacitance generated when forming the etching protective layer in the prior art and thereby effectively improve the performance of the oxide thin film transistor. In addition, the etching protective layer can prevent the back channel from damage during etching the source and drain or depositing the insulating passivation layer, and thus can further effectively improve the characteristics of the oxide thin film transistor.

Referring to FIG. 2, a schematic cross-sectional structural view of an embodiment of an oxide thin film transistor of the invention is shown.

As shown in FIG. 2, the thin film transistor in this embodiment includes a first substrate 201, a gate electrode 202 disposed on the first substrate 201, a gate insulating layer 203 disposed on the gate electrode 202, and an oxide semiconductor layer 204 disposed on the gate insulating layer 203.

The gate electrode 202 is formed by that forming a metal film on the first substrate by a deposition process and then using a first mask to perform an exposure and an etching on the metal film. The etching process generally is a process of removing a part of thin film unmasked by a resist film to form a pattern on the thin film same as that of the resist film. The etching process generally is dry etching or wet etching, and in this embodiment, it is not limited as long as it can etch the metal film to form the gate electrode.

The first mask is an ordinary mask only for etching one layer.

The gate insulating layer 203 and the oxide semiconductor film 204 also are formed by deposition processes. The deposition process generally is that depositing a foreign substance(s) on a substrate surface to form a thin film, and also is referred to as vapor deposition. In this embodiment, the metal film is formed by depositing a metal substance(s) on a surface of the first substrate; and in other embodiment, the metal film may be formed by other deposition method and it is not limited herein.

The first substrate may be a glass substrate or a quartz substrate, and in other embodiment, other substrate may be used and is not limited herein. The metal film includes at least one of aluminium (Al), molybdenum (Mo), copper (Cu) and silver (Ag) and is not limited herein.

The gate insulating layer includes at least one of silicon nitride (SiNx) and amorphous silicon oxide (SiOx), and in other embodiment, other insulating substance may be used and is not limited herein.

The oxide semiconductor film is a transparent oxide and includes at least one of zinc oxide (ZnO) based, tin dioxide (SnO2) based and indium oxide (In2O3) based transparent oxide; and in other embodiment, other transparent oxide may be used as long as it can achieve the function of the oxide semiconductor film of this embodiment and is not limited herein.

A first metal layer 205 is disposed on the oxide semiconductor film 24. A source electrode 206 and a drain electrode 207 separated by a channel are disposed on the first metal layer 205. The channel (not labeled) exposes a metal oxide layer 208 formed by an oxidized portion of the first metal layer 205.

The first metal layer 205 is formed on the oxide semiconductor film 204 by deposition. The first metal layer is thin and includes at least one of metals such as aluminium (Al) and titanium (Ti), and in other embodiment, other metal with same property may be used and is not limited herein. A thickness of the first metal layer 205 is 5 nm-10 nm.

The source electrode 206 and the drain electrode 207 separated by the channel are obtained by using a second mask to etch a second meta layer (not shown) disposed on the first metal layer to form the channel and pattern active regions of the drain electrode and the source electrode separated by the channel. The drain electrode and the source electrode are separated by the channel and located at two sides of the gate electrode respectively.

The second metal layer generally includes at least one of molybdenum (Mo) and silver (Ag), and in other embodiment, other metal with the same property may be used and is not limited herein.

The second mask includes one of half-tone mask process, gray-tone mask process and single slit mask process; and in other embodiment, other process may be used as long as it can achieve the patterning of the active regions of the drain electrode and the source electrode by one mask and is not limited herein.

The metal oxide layer 208 is obtained by oxidizing the exposed portion of the first metal layer 205 by an oxygen plasma and used as an etching protective layer for protecting a back channel. In other embodiment, an atmosphere containing oxygen plasma may be used to oxide the exposed portion of the first metal layer instead and is not limited herein.

In another embodiment, surfaces of the source electrode 206 and the drain electrode 207 are covered by a photoresist.

In addition, an insulating passivation layer 209 is disposed overlying a surface of the oxide thin film transistor. The insulating passivation layer 209 is disposed overlying the drain electrode 207, the metal oxide layer 208 and the source electrode 206. The insulating passivation layer 209 is disposed with contact holes 210, and the contact holes 201 are disposed with contact electrodes 211 therein. The contact electrodes 211 respectively are electrically contacted with the source electrode 206 and the drain electrode 207.

The contact holes 210 are formed by using a third mask to perform an etching on the insulating passivation layer 209. The contact electrodes 211 are formed in the contact holes 210 by a fourth mask.

The third mask and the fourth mask each are an ordinary mask only for etching one layer.

The insulating passivation layer 209 includes at least one of silicon nitride (SiNx) and amorphous silicon oxide (SiO2); and in other embodiment, other insulating passivation substance with the same property may be used and is not limited herein. The contact electrodes 211 are indium tin oxide (ITO) electrodes, and in other embodiment, it may replace the ITO electrodes as other electrodes and is not limited herein.

Different from the prior art, the oxide thin film transistor in this embodiment includes a first substrate, and a gate electrode, a gate insulating layer and an oxide semiconductor layer disposed on the first substrate, and further includes a source electrode and a drain electrode separated by a channel and disposed on a first metal layer. The channel exposes a metal oxide layer formed by an oxidized portion of the first metal layer. The source electrode and the drain electrode are formed by a special mask, which can simultaneously form the channel and pattern active regions of the source electrode and the drain electrode separated by the channel, compared with the prior art, one mask process can be reduced, the manufacturing process of the oxide thin film transistor can be simplified and the manufacturing time and cost can be reduced. The channel exposes the metal oxide layer formed by the oxidized portion of the first metal layer to form an etching protective layer for protecting a back channel, and there is no need of mask during the oxidization process of the first metal layer, compared with the prior art, it not only can reduce one mask again, simplify the manufacturing process of oxide thin film transistor and reduce the manufacturing time and cost, but also the etching protective layer can prevent the back channel from damage when etching the source electrode and drain electrode or depositing the insulating passivation layer and thereby can effectively improve the characteristics of the oxide thin film transistor.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method of an oxide thin film transistor, comprising:
depositing a metal film on a first substrate and forming a gate electrode by exposure and etching on the metal film;
sequentially depositing a gate insulating layer and an oxide semiconductor film;
sequentially forming a first metal layer and a second metal layer on the oxide semiconductor film and etching the second metal layer by a half-tone mask process, a gray-tone mask process or a single slit mask process to form a channel and a pattern of active regions of a drain electrode and a source electrode separated by the channel;
etching a part of the second metal layer outside the pattern of the active regions;
etching a part of the second metal layer corresponding to the channel to expose a portion of the first metal layer;
oxidizing the exposed portion of the first metal layer;
forming an insulating layer and disposing contact electrodes.

2. The manufacturing method according to claim 1, wherein the step of oxidizing the exposed portion of the first metal layer comprises:
using an oxygen plasma to oxidize the exposed portion of the first metal layer to thereby form a metal oxide layer for protecting a channel.

3. The manufacturing method as claimed in claim 1, wherein the gate insulating layer comprises at least one of silicon nitride (SiNx) and amorphous silicon oxide (SiOx); the oxide semiconductor film is a transparent oxide and comprises at least one of zinc oxide (ZnO) based, tin dioxide (SnO₂) based and indium oxide (In₂O₃) based transparent oxides.

4. The manufacturing method as claimed in claim 1, wherein the first substrate comprises one of glass substrate and quartz substrate; the metal film comprises at least one of aluminium (Al), molybdenum (Mo), copper (Cu) and silver (Ag).

5. The manufacturing method as claimed in claim 1, wherein a thickness of the first metal layer is in the range from 5 n to 10 nm.

6. The manufacturing method as claimed in claim 1, wherein the step of forming an insulating passivation layer and disposing contact electrodes comprises:
depositing the insulating passivation layer, forming contact holes on the insulating passivation layer by etching, and forming the contact electrodes in the contact holes.

7. The manufacturing method as claimed in claim 1, wherein the insulating passivation layer comprises at least one of silicon nitride (SiNx) and amorphous silicon oxide (SiOx); the contact electrodes are indium tin oxide (ITO) electrodes.

8. A manufacturing method of an oxide thin film transistor, comprising:
sequentially forming a gate electrode, a gate insulating layer and an oxide semiconductor film in that order on a first substrate;
sequentially forming a first metal layer and a second metal layer in that order on the oxide semiconductor film, and forming a drain electrode and a source electrode on the second metal layer, the source electrode and the drain electrode being separated by a channel, and the channel exposing a portion of the first metal layer;
oxidizing the exposed portion of the first metal layer;
forming an insulating passivation layer and disposing contact electrodes.

9. The manufacturing method as claimed in claim 8, wherein the step of sequentially forming a first metal layer and a second metal layer in that order on the oxide semiconductor film, and forming a drain electrode and a source electrode on the second metal layer, the source electrode and the drain electrode being separated by a channel, and the channel exposing a portion of the first metal layer comprises:
etching the second metal layer by a half-tone mask process, a gray-tone mask process or a single slit mask process to form the channel and a pattern of active regions of the drain electrode and the source electrode separated by the channel;
etching off a portion of the second metal layer outside the pattern of the active regions;
etching off a portion of the second metal layer corresponding to the channel to expose the portion of the first metal layer.

10. The manufacturing method as claimed in claim 8, wherein the step of oxidizing the exposed portion of the first metal layer comprises:
using an oxygen plasma to oxidize the portion of the first metal layer to thereby form a metal oxide layer for protecting a channel.

11. The manufacturing method as claimed in claim 8, wherein the step of sequentially forming a gate electrode, a gate insulating layer and an oxide semiconductor film in that order on a first substrate comprises:
depositing a metal film on the first substrate and forming the gate electrode by exposure and etching on the metal film;
sequentially depositing the gate insulating layer and the oxide semiconductor film.

12. The manufacturing method as claimed in claim 11, wherein the gate insulating layer comprises at least one of silicon nitride (SiNx) and amorphous silicon oxide (SiOx); the oxide semiconductor film is a transparent oxide and comprises at least one of zinc oxide (ZnO) based, tin dioxide (SnO₂) based and indium oxide (In₂O₃) base transparent oxides.

13. The manufacturing method as claimed in claim 11, wherein the first substrate comprises a glass substrate or a quartz substrate; the metal film comprises at least one of aluminium (Al), molybdenum (Mo), copper (Cu) and silver (Ag).

14. The manufacturing method as claimed in claim 8, wherein a thickness of the first metal layer is in the range from 5 nm to 10 nm.

15. The manufacturing method as claimed in claim 8, wherein the step of forming an insulating passivation layer and depositing contact electrodes comprises:
depositing the insulating passivation layer, forming contact holes on the insulating passivation layer by etching, and forming the contact electrodes in the contact holes.

16. The manufacturing method as claimed in claim 15, wherein the insulating passivation layer comprises at least one of silicon nitride (SiNx) and amorphous silicon oxide (SiOx); the contact electrodes are indium tin oxide (ITO) electrodes.

17. An oxide thin film transistor comprising: a first substrate, a gate electrode disposed on the first substrate, a gate insulating layer disposed on the gate electrode and an oxide semiconductor film disposed on the gate insulating layer; further comprising a first metal layer disposed on the oxide semiconductor film, and a source electrode and a drain electrode separated by a channel and disposed on the first metal layer, wherein the channel exposes a metal oxide layer formed by an oxidized portion of the first metal layer;
wherein the oxide thin film transistor further comprises an insulating passivation layer, the insulating passivation layer being disposed overlying the drain electrode, the metal oxide layer and the source electrode, the insulating passivation layer further being disposed with contact electrodes.
